(19) United States
(12) Patent Application Publication
(10) Pub. No.: US 2020/0134438 A1
(43) Pub. Date: Apr. 30, 2020

(54) DYNAMIC RANGE AND LINEARITY OF RESISTIVE ELEMENTS FOR ANALOG COMPUTING

(71) Applicant: Taiwan Semiconductor Manufacturing Company, Ltd., Hsinchu (TW)

(72) Inventors: Randy Osborne, Beaverton, OR (US); Kevin Xiaoqiang Zhang, Hsinchu (TW)

(73) Assignee: Taiwan Semiconductor Manufacturing Company, Ltd., Hsinchu (TW)

(21) Appl. No.: 16/600,888

(22) Filed: Oct. 14, 2019

Related U.S. Application Data
(60) Provisional application No. 62/750,349, filed on Oct. 25, 2018.

(51) Int. Cl. G06N 3/063; G11C 11/54; G11C 13/00; G11C 11/40

(52) U.S. Cl. CPC G06N 3/0635; G11C 11/40; G11C 13/0002; G11C 11/54

(57) ABSTRACT

A resistive network include multiple resistive units; each resistive unit is made up of multiple resistive elements, which can be arranged in a parallel configuration. Each of the resistive elements can be programmable (e.g., switched on or off, or set to one of multiple resistance values). Furthermore, a method of analog computing includes configuring multiple resistive elements in each of multiple resistive units and configuring the resistive units into a network. The configuration of the resistive elements can be, for example, arranging them into a parallel combination. The method further includes programming each resistive unit, for example, by switching individual resistive elements into, or out of, the parallel combination.

### BACKGROUND

This disclosure relates generally resistive elements such as those used in certain analog computing applications. This disclosure more specifically relates to a network of resistive elements with improved dynamic range and linearity.

In certain analog computers, which find application in, among other things, artificial intelligence, networks of resistive elements (or units having respective resistance elements) are used to control current levels for computing. The range of conductance of the resistive elements significantly affects the performance of the analog computers. Efforts therefore are ongoing in resistive element design.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a portion of an analog computing device according to some embodiments.

FIG. 2 schematically illustrates a resistive assembly in the analog computing device of FIG. 1 according to some embodiments.

FIG. 3 schematically illustrates details of a portion of the analog computing device of FIG. 1 according to some embodiments.

FIG. 4 schematically illustrates a portion of another analog computing device according to some embodiments.

FIG. 5 outlines a method of analog computing according to some embodiments.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Analog computing is useful in a wide range of applications, especially in computations, simulations and implementations relating to complex systems, such as neurological systems. For example, artificial neural networks (or simply “neural networks” as used in this disclosure) have been used to achieve machine learning in artificial intelligence (“AI”) systems. One example type of neural network includes logically sequentially arranged layers of nodes, or artificial neurons. The layers include an input layer, an output layer, a one or more intermediate layers (so-called “hidden layers”). The nodes in input layer receives input signals from external sources, akin to signals from synapse in biological systems, and output signals to the hidden layers. Each node in a hidden layer receives signals from the nodes in the immediate upstream layer and outputs signals to the nodes in the immediate downstream layer. Each node in the output layer receives the signals from the last hidden layer and produces an output signal. In some example neural networks, the output signal from each node in a layer is a function of the weighted sum of signals from all nodes in the upstream layer. That is, each signal, xᵢ, from the upstream layer is multiplied (weighted) by a weight, wᵢⱼ, and a function, ƒ of the sum of the weighted signals, Σᵢwᵢⱼxᵢ, is the signal, Yⱼ^{B}, generated at the j-th node of the downstream layer:

Yⱼ^{B}=ƒ(Σᵢwᵢⱼxᵢ),

where ƒ can be of a variety of forms suitable for neural network implementations. Examples of such functions include linear (e.g., ƒ(x)=x, or Yⱼ^{B}=Σᵢwᵢⱼxᵢ) the sigmoid function (ƒ(x)=1 (1+e^{-x})), and rectifier function (ƒ(x)=max(0, x)).

In some embodiments, analog computing system includes a resistor network connecting successive layers of nodes, such as between the input layer and the first hidden layer. In these embodiments, each node in a layer is connected to several, or all, of the nodes in the upstream layer through a respective resistive assembly, the resistance of which is adjustable. The signal, in the form of the current, generated at each node is thus the sum of the products between the currents at the nodes of the upstream layer and the conductances of the respective resistive assemblies. The conductances are therefore the weights for the signals from the respective nodes in the upstream layer. In some embodiments, each resistive assembly includes multiple switched resistive branches connected in parallel to each other.

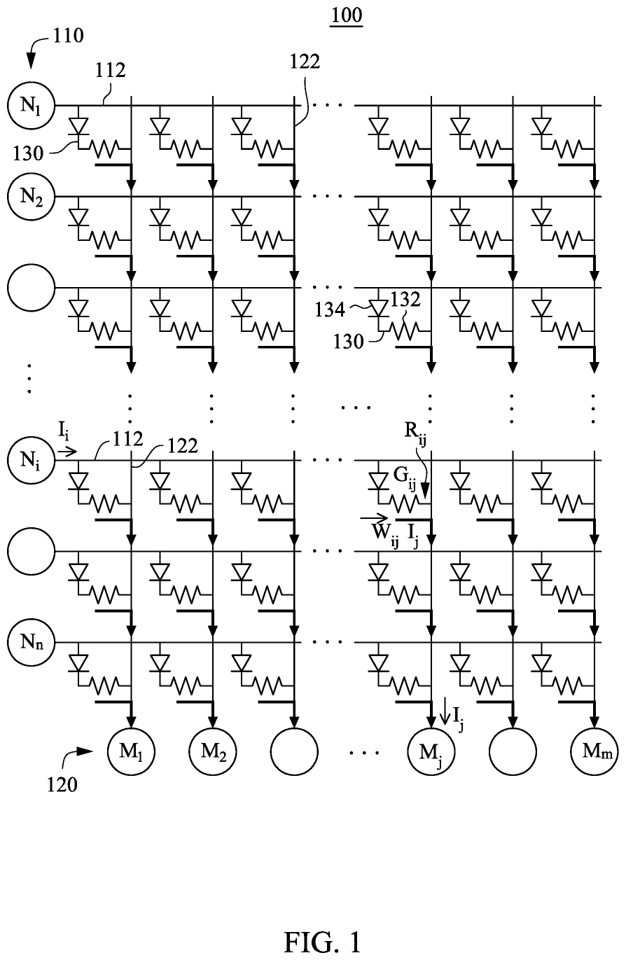

As a specific example, as shown in FIG. 1, in a portion of a neural network (or more generally, an analog computer) 100, an upstream layer 110 includes n nodes N₁, N₂, . . . , Nₙ; a downstream layer 120 includes m nodes M₁, M₂, . . . , Mₘ. The neural network 100 further includes conductive paths 112, each connected to a respective node Nᵢ in the upstream layer 110, and conductive paths 122, each connected to a respective node Mⱼ in the downstream layer 120. A resistive assembly 130 is connected between each pair of nodes Nᵢ and Mⱼ, directly or via the conductive paths 112, 122. In this example, there are n×m resistive assemblies 130, one for each i-j pair, where i=1, 2, . . . , n, and j=1, 2, . . . , m. In other embodiments, resistive assemblies 130 can be absent for one or more i-j pairs.

The resistive assembly is symbolically illustrated by a resistive element R 132 and a selecting element 134 but are implemented by multiple resistive and selective elements, as explained in more detail below. Each resistive assembly 130 has a conductance, Gᵢⱼ=1/Rᵢⱼ, where Rᵢⱼ is the resistance of the resistive assembly. For a node current, Iⱼ, from the node Nᵢ, the resistive assembly contributes a current Gᵢⱼ·Iᵢ to the current, at the node Mⱼ. Iⱼ is thus a sum of Gᵢⱼ·Iᵢ over all i=1, 2, . . . , n:

Iⱼ=Σᵢ₌₁ⁿGᵢⱼIᵢ,j=1,2, . . . ,m.

The signal (current) at each node M₁ is thus a weighted sum of the signals (currents) at the upstream nodes:

Iⱼ=Σᵢ₌₁ⁿwᵢⱼIᵢ, where wᵢⱼ=Gᵢⱼ,j=1,2, . . . ,m.

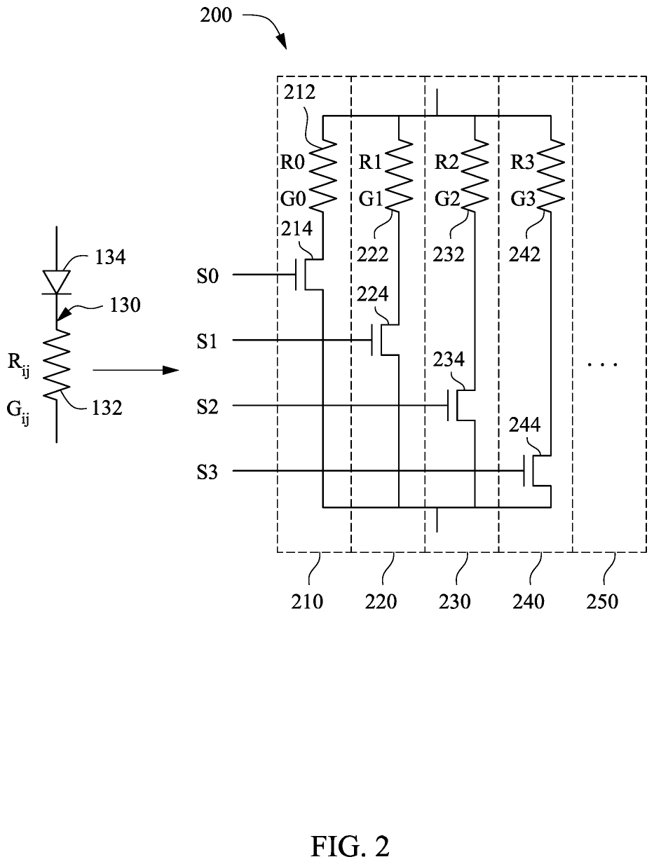

Referring to FIG. 2, according to some embodiments, each resistive assembly 130 can be a combination of multiple resistive elements, at least a subset of which is switched. In the example shown in FIG. 2, the resistive assembly is made of a combination 200 of several switched resistive branches 210,220,230,240,250 connected in parallel. Although four resistive branches are explicitly depicted in the example in FIG. 2, any number (N) of resistive branches can be included.

Each branch includes a resistive element and a selecting, or switching element. In this example, resistive branch 210 includes a resistor 212, having a resistance R₀ (and conductance G₀=1/R₀), in series with a switching transistor 214 (such as a field-effect transistor (FET)), which can be turned on or off by a selecting signal S₀ at the control terminal (such as the gate) of the switching transistor 214 to select and de-select the resistor 212. Resistive branch 220 includes a resistor 222, having a resistance R₁ (and conductance G₁=1/R₁), in series with a switching transistor 224 (such as a field-effect transistor (FET)), which can be turned on or off by a selecting signal S₁ at the control terminal (such as the gate) of the switching transistor 224 to select and de-select the resistor 222. Resistive branch 230 includes a resistor 222, having a resistance R₂ (and conductance G₂=1/R₂), in series with a switching transistor 234 (such as a field-effect transistor (FET)), which can be turned on or off by a selecting signal S₂ at the control terminal (such as the gate) of the switching transistor 234 to select and de-select the resistor 232. Resistive branch 240 includes a resistor 242, having a resistance R₃ (and conductance G₃=1/R₃), in series with a switching transistor 244 (such as a field-effect transistor (FET)), which can be turned on or off by a selecting signal S₃ at the control terminal (such as the gate) of the switching transistor 244 to select and de-select the resistor 242. Different

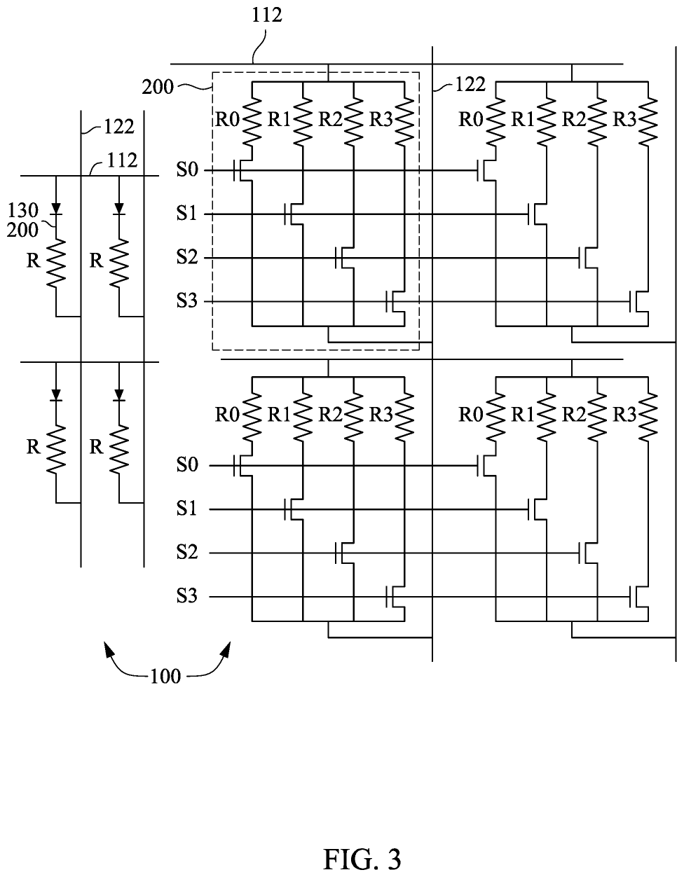

As shown in FIG. 3, multiple combinations 200 as described above can be used to interconnect respective pairs of nodes between two layers. Depending on the specific design, combinations 200 can be used to form all connections between respective pairs of nodes. Alternatively, combinations 200 can be used to form connections between respective pairs of nodes for only some pairs of nodes. In some embodiments, combinations 200 between the same two layers include different numbers of switched resistive elements.

The resistive elements depicted in the specific example in FIGS. 2 and 3 are resistors but can be any suitable resistive element. Examples of other types of resistive elements include resistive random access memory (“RRAM”) cells, such as phase-change memory (“PCM”) devices and magnetic random access memory (“MRAM”) cells. Certain types of such devices are multi-level resistance devices, i.e., devices capable of having more levels of resistance than binary, high/low values. For example, certain RRAM devices are capable of having four, eight, or higher number of resistance values.

Given a pattern of the resistive elements selected (i.e., the corresponding switching transistors turned on) in a resistive assembly 130, the conductance, G, of the assembly is the sum of the conductances of the selected resistors. For a resistive assembly 130 having N switched resistive elements 210, . . . , 250 of equal conductance g, G has N+1 values: 0, 1g, 2g, . . . , Ng. More values of G can be attained with resistive elements of different conductances.

For resistive elements, such as RRAMs, that are capable of having multiple levels of resistance values, more values of total conductance G can be achieved. For a parallel combination of N resistive elements, each of which have L programmable conductance values, g₁, g₂, . . . , g_{L}, the total conductance G can be programmed to have the levels:
N·g₁
(N−1)·g₁+g₂
(N−2)·g₁+2·g₂
. . .
g_{(L-1)}+(N−1)·g_{L}
. . .
N·g_{L}

Thus, the dynamic range of the connection between two nodes is increased from L levels spanning g₁ to g_{L} for a single resistive element to Total(N,L) levels spanning N·g₁ to N·g_{L}, where Total(N,L) is defined as

$$Total ( N , L ) = {\sum }_{i = 1}^{L} Total ( N - 1 , i )$$

In some embodiments, all resistive elements have substantially the same conductance. In such embodiments, the number of the levels of G, Total(N,L), as a function of N and L are shown in the following table:

| | | L | | | | | | | |
|---|---|---|---|---|---|---|---|---|---|
| Total (N, L) | | 1 | 2 | 3 | 4 | 5 | 6 | 7 | 8 |
| N | 1 | 1 | 2 | 3 | 4 | 5 | 6 | 7 | 8 |
| | 2 | 1 | 3 | 6 | 10 | 15 | 21 | 28 | 36 |
| | 3 | 1 | 4 | 10 | 20 | 35 | 56 | 54 | 120 |
| | 4 | 1 | 5 | 15 | 35 | 70 | 126 | 210 | 330 |
| | 5 | 1 | 6 | 21 | 56 | 126 | 252 | 462 | 792 |
| | 5 | 1 | 7 | 25 | 84 | 210 | 462 | 524 | 1716 |
| | 7 | 1 | 5 | 36 | 120 | 330 | 792 | 1716 | 3432 |
| | S | 1 | 9 | 45 | 165 | 495 | 1287 | 3003 | 6435 |

For example, it is possible to achieve 330 levels of G with four resistive elements, each having eight levels of resistance, in a resistive assembly. More resistance levels can be achieved with resistive elements of non-identical resistances.

Even though, as shown in the table above, a large number of programmable conductance levels can be achieved with some embodiments, a subset of the levels may be selected in certain actual applications. For example, in certain neural network implementations by analog computing it is desirable to have the conductance G be linear in the programming pulse, i.e., having substantially equal size increments. However, as conductance of a resistive element is the reciprocal of its resistance, the conductance, 1/R, is highly non-linear, with the resistance states of interest clustered around the lower end of the resistance values of the element. At the same time, the smaller the difference between the value of resistive states the more precision and time are required to write the state. Improved linearity, in accordance with some embodiments, can be achieved by limiting the selection of levels to a subset of all possible levels. For example, in selecting the resistance of a multi-level resistance device, the selection can be limited to only some of the available higher-resistance values, such that the successively selected conductance values are spaced from each other substantially equally. At the same time, to address the more precision and time required to write the state for low-resistance end of the resistive states, more resistive elements can be connected in parallel to fine tune the conductance levels.

In some embodiments, such as those shown in FIGS. 2 and 3, each set of parallel resistive elements 200 provide a single weight, wᵢⱼ, for a pair of nodes in the adjacent layers. For such a configuration, the conductance can be changed according to any desired procedure. For example, if RRAM elements are used to generate wᵢⱼ, each RRAM can be programmed to reduce resistance (increase conductance) incrementally, corresponding to increased coupling between the nodes, but only abruptly increase the resistance (to infinity, for example) (decrease conductance, to zero, for example), as in the example of a reset. In some embodiments, likewise, parallel resistive elements R₀, R₁, R₂, R₃, . . . R_{N} can be incrementally added, corresponding to incremental increase of conductance, or coupling by each signal pulse that activates the corresponding switching device (such as switching transistor) that connects the resistive element into the parallel configuration. Where the resistance values of the parallel resistive elements are substantially equal, the incremental increase of conductance results in a linear sweep of conductance as a function of the activation pulses.

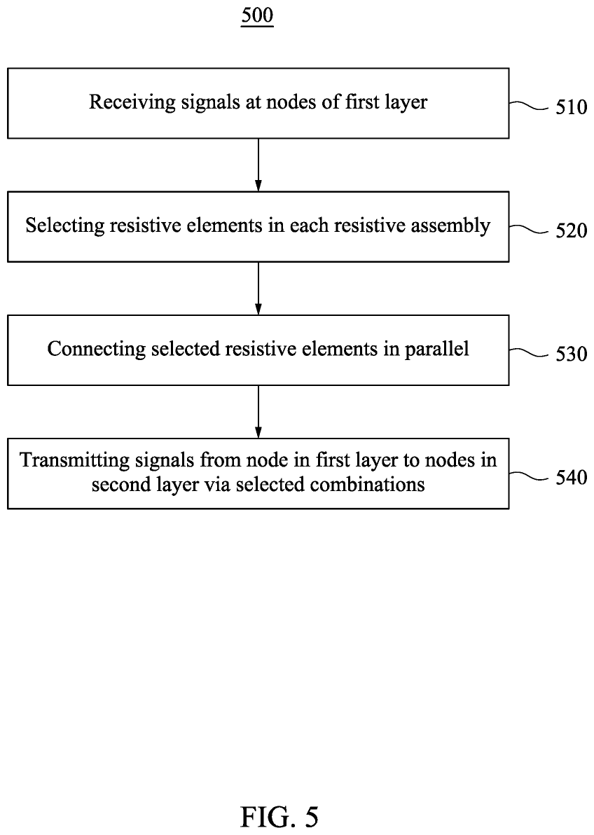

In some embodiments, in operation 500, as outlined in FIG. 5, a first plurality of signals are received 510 at a respective first plurality of nodes. At least a subset of a plurality of resistive elements in each of a first plurality of resistive assemblies are selected 520; each of a first plurality of resistive assemblies, the selected resistive elements are configured 530 into a parallel combination. Then, at least a subset of the signals are transmitted 540 from a respective subset of the first plurality of nodes to one of a second plurality of nodes via the respective parallel combinations.

In some embodiments, during operation, such as inferencing for neural network, all the selectors are enabled in an initialization step. During training, the resistive elements are programmed (have their respective resistances set) one at time by disasserting N−1 signals and only asserting the control signal corresponding to the resistive element to be programmed. Resistive elements are selected according to the conductance required, or incrementally selected or deselected. The selected programmed resistive elements are then placed in parallel connection with each other to provide the total conductance (i.e., weight) for each pair of node in the neighboring layers.

In some embodiments, each group of N parallel-connected resistive elements, such as those shown in FIG. 2, can be divided into M subsets (e.g., M₁, M₂, . . . , M_{M}, where M₁+M₂+ . . . +M_{M}=N), where each subset represents a weight. M weights for each pair of nodes can thus be stored. In some embodiments, during inferencing and training phases, only the elements corresponding to a given subset (e.g., M₁) are selected across the entire array. Such an arrangement enables a form of multi-tasking, where analog computing can switch from computing with one set of weights (e.g., M₁) to another set of weights (e.g., M₂) by simply changing the selected weights, rather than reloading values from some other storage.

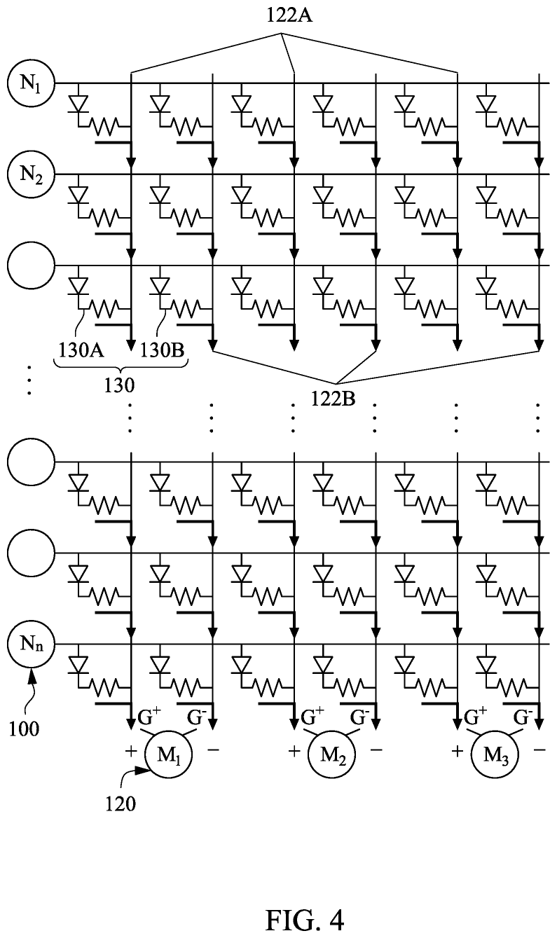

In further embodiments, an example of which is shown in FIG. 4, the N resistive elements in each resistive assembly 130 can be divided into two subsets 130A, 130B, with one subset (e.g., 130A) representing positive weights and another subset (e.g., 130B) representing negative weights. The positive and negative weight formulation is useful for certain non-volatile memory (“NVM”) resistive elements that have asymmetric ability to accept incremental writes. For example, RRAM elements can be written incrementally to reduce resistance but can only abruptly increase resistance, i.e., by a reset, corresponding to terminating connections. The analog computing operation can be performed sequentially, first performing the multiply accumulate for the positive weights and sensing the result, G⁺, and repeat the same for the negative weights (by sequencing the select signals accordingly) and sensing the result, G⁻, and finally taking the difference G⁺−G⁻ in the results. The difference signal G⁺−G⁻ can be obtained by any suitable device and method, including, for example, differential amplifiers, such as differential current amplifiers.

Certain embodiments disclosed herein offers advantages over traditional analog computing devices. With the use of parallel resistive elements, fewer resistance levels per resistive element are needed, the precision in the signals for setting those levels in each resistive element (e.g., RRAM) becomes less critical; the write time for such resistive element can thus be reduced, thereby increasing the speed of analog computing. Moreover, redundancy can be achieved by providing extra resistive elements in each resistive assembly; the extra resistive elements can be selected as needed, such the case in which any other resistive element is defective.

Thus, certain embodiments disclosed herein achieve a high number of weight levels for analog computing using resistive elements, such as MRAM, that have limited number of resistance levels, and afford faster write time and redundancy.

According to certain embodiments, each resistive unit in a resistive network of resistive units is made up of multiple resistive elements, which can be arranged in a parallel configuration. Each of the resistive elements can be programmable (e.g., switched on or off). For example, each of the resistive elements can be a serial combination of a resistor and a switch device, such as a switching transistor.

According to certain other embodiments, a method of analog computing includes configuring multiple resistive elements in each of multiple resistive units and configuring the resistive units into a network. The configuration of the resistive elements can be, for example, arranging them into a parallel combination. The method further includes programming each resistive unit, for example, by switching individual resistive elements into, or out of, the parallel combination.

Thus, in accordance with a disclosed embodiment, an analog neural network, or more generally, an analog computer, includes a first plurality of nodes, a second plurality of nodes, and a first plurality of resistive assemblies. Each of the first plurality of resistive assemblies has a plurality of resistive elements connected to each other in parallel, and at least a subset of the first plurality of resistive elements are switched resistive elements. At least a subset of the first plurality of nodes are connected to a common one of the second plurality of nodes via respective ones of the first plurality of resistive assemblies.

In accordance with other disclosed embodiments, a method of computing includes receiving a first plurality of signals at a respective first plurality of nodes, and selecting at least one subset of a plurality of resistive elements in each of a first plurality of resistive assemblies. For each of the first plurality of resistive assemblies, the selected resistive elements are configured into a parallel combination. At least one subset of the signals from a respective subset of the first plurality of nodes is transmitted to a first one of a second plurality of nodes via the respective parallel combinations.

In accordance with a further embodiment, an artificial neural network includes an upstream layer comprising a first plurality of nodes adapted to receive a respective plurality of signals, and a downstream layer comprising a second plurality of nodes. A plurality of resistance assemblies is provided, each of which comprises a plurality of resistive elements in a parallel configuration, where at least one of the resistive elements is a switched resistive element. The switched resistive element in each resistive assembly include a resistive device and a switching device configured to connect the resistive device in parallel with the other resistive elements in the resistive assembly.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An analog computer, comprising:
a first plurality of nodes;
a second plurality of nodes; and
a first plurality of resistive assemblies, each comprising a plurality of resistive elements connected to each other in parallel, at least a subset of the first plurality of resistive elements being switched resistive elements,
at least a subset of the first plurality of nodes are connected to a common one of the second plurality of nodes via respective ones of the first plurality of resistive assemblies.

2. The analog computer of claim 1, wherein at least a subset of the second plurality of nodes are connected to a common one of the first plurality of nodes via respective ones of the first plurality of resistive assemblies.

3. The analog computer of claim 2, wherein each combination of a node in the first plurality of nodes and a node in the second plurality of node are interconnected via a respective one of the first plurality of resistive assemblies.

4. The analog computer of claim 1, wherein each of the switched resistive elements comprises a resistive device and a switching transistor connected in series with the resistive device.

5. The analog computer of claim 1, wherein each of the first plurality of resistive elements comprises a resistor.

6. The analog computer of claim 1, wherein each of the first plurality of resistive elements comprises a multilevel resistance device.

7. The analog computer of claim 6, wherein each of the multilevel resistance devices comprises a resistive random access memory (RRAM) element.

8. The analog computer of claim 1, further comprising:
a third plurality of nodes; and
a second plurality of resistive assemblies, each comprising a plurality of resistive elements connected to each other in parallel, at least a subset of the plurality of resistive elements being switched resistive elements,
at least a subset of the second plurality of nodes are connected to a common one of the third plurality of nodes via respective ones of the second plurality of resistive assemblies.

9. The analog computer of claim 3, further comprising:
a third plurality of nodes; and
a second plurality of resistive assemblies, each comprising a plurality of resistive elements connected to each other in parallel, at least a subset of the plurality of resistive elements being switched resistive elements,
wherein each combination of a node in the second plurality of nodes and a node in the third plurality of node are interconnected via a respective one of the second plurality of resistive assemblies.

10. The analog computer of claim 9, wherein:
each of the first plurality of resistive assemblies is configurable into:
a first configuration wherein a first subset of the plurality of resistive elements in each of the first plurality of resistive assemblies are adapted to be connected to each other in parallel;
a second figuration wherein a second subset of the plurality of resistive elements in each of the first plurality of resistive assemblies are adapted to be connected to each other in parallel; and
each of the second plurality of resistive assemblies is configurable into:
a first configuration wherein a first subset of the plurality of resistive elements in each of the second plurality of resistive assemblies are adapted to be connected to each other in parallel;
a second configuration wherein a second subset of the plurality of resistive elements in each of the second plurality of resistive assemblies are adapted to be connected to each other in parallel;
the analog computer being configurable into a plurality of mutually exclusive states in which:
in a first of the plurality of states, both the first and second pluralities of resistive assemblies are configured into the respective first configuration, and
in a second of the plurality of states, both the first and second pluralities of resistive assemblies are configured into the respective second configuration.

11. The analog computer of claim 1, wherein at least a second subset of the first plurality of nodes are connected to a second common one of the second plurality of nodes via respective ones of the plurality of resistive assemblies, the analog computer further comprising a differential amplifier adapted to receive a first output signal from the first common one of the second plurality of nodes and a second output signal from the second common one of the second plurality of nodes and to generate an output signal indicative of the difference between the first and second output signals.

12. The analog computer of claim 1, wherein each of the first plurality of nodes is adapted to receive a current signal, and the first plurality of the resistive assemblies are adapted to generate at each of the second plurality of nodes a respective weighted sum of the current signals received at the first plurality of nodes.

13. A method of computing, comprising:
receiving a first plurality of signals at a respective first plurality of nodes;
selecting at least one subset of a plurality of resistive elements in each of a first plurality of resistive assemblies;
for each of the first plurality of resistive assemblies, configuring the selected resistive elements into a parallel combination; and
transmitting at least one subset of the signals from a respective subset of the first plurality of nodes to a first one of a second plurality of nodes via the respective parallel combinations.

14. The method of claim 13, wherein the transmitting at least a subset of the signals comprises transmitting each of the at least one subset of the signals from each of a respective subset of the first plurality of nodes to each one of the second plurality of nodes via a respective one of the parallel combinations.

15. The method of claim 14, further comprising setting a resistance value of each of the at least one subset of a plurality of resistive elements in each of the first plurality of resistive assemblies to one of a plurality of resistance values.

16. The method of claim 14, further comprising:
selecting at least one subset of a plurality of resistive elements in each of a second plurality of resistive assemblies;
for each of the second plurality of resistive assemblies, configuring the selected resistive elements into a parallel combination; and
transmitting at least one subset of the signals from a respective subset of the second plurality of nodes to one of a third plurality of nodes via the respective parallel combinations.

17. The method of claim 16, further comprising:
setting resistance values of a first subset of resistive elements of each of the first plurality of resistive assemblies and a second subset of resistive element of the first plurality of resistive assemblies;
setting resistance values of a first subset of resistive elements of each of the second plurality of resistive assemblies and a second subset of resistive element of the second plurality of resistive assemblies;
wherein:
the transmitting at least one subset of the signals from the first to second plurality of nodes comprises, after the setting of the resistance values and without thereafter changing any of the set values, transmitting the signals via the first subset of resistive elements of each of the first plurality of resistive assemblies during a first time period and transmitting the signals via the second subset of resistive elements of each of the first plurality of resistive assemblies during a second time period; and
the transmitting at least one subset of the signals from the second to third plurality of nodes comprises, after the setting of the resistance values and without thereafter changing the values, transmitting the signals via the first subset of resistive elements of each of the second plurality of resistive assemblies during a second time period and transmitting the signals via the second subset of resistive elements of each of the second plurality of resistive assemblies during a second time period.

18. The method of claim 13, further comprising:
selecting at least one subset of a plurality of resistive elements in each of a second plurality of resistive assemblies;
for each of the second plurality of resistive assemblies, configuring the selected resistive elements into a parallel combination; and
transmitting the at least one subset of the signals from the respective subset of the first plurality of nodes to a second one of a second plurality of nodes via the respective parallel combinations;
the method further comprising generating a signal indicative of the difference between a combination of the signals transmitted to the first one of the second plurality of nodes and a combination of the signals transmitted to the second one of the second plurality of nodes.

19. An artificial neural network, comprising:
an upstream layer comprising a first plurality of nodes adapted to receive a respective plurality of signals;
a downstream layer comprising a second plurality of nodes; and
a plurality of resistance assemblies, each of which comprises a plurality of resistive elements in a parallel configuration, at least one of the resistive elements being a switched resistive element;
the switched resistive element in each resistive assembly comprising a resistive device and a switching device configured to connect the resistive device in parallel with the other resistive elements in the resistive assembly.

20. The artificial neural network of claim 19, wherein each of the switching devices comprises a control input adapted to receive a select-signal, the switching device adapted to connect the respective resistive device in parallel with the other resistive elements in the resistive assembly upon receiving the select-signal, each of the resistive elements comprising a multi-level resistance device.
